(19) United States
(12) Patent Application Publication
(10) Pub. No.: US 2013/0168144 A1
(43) Pub. Date: Jul. 4, 2013

(54) PRINTED CIRCUIT BOARD AND METHOD FOR MANUFACTURING THE SAME

(71) Applicant: Samsung Electro-Mechanics Co., Ltd., Gyeonggi-do (KR)

(72) Inventors: Sung Won Jeong, Chungcheongnam-do (KR); Seon Jae Mun, Gyeonggi-do (KR); Boo Yang Jung, Gyeonggi-do (KR); Dae Young Lee, Gyeonggi-do (KR); Jin Won Choi, Gyeonggi-do (KR)

(73) Assignee: Samsung Electro-Mechanics Co., Ltd., Gyeonggi-do (KR)

(21) Appl. No.: 13/717,504

(22) Filed: Dec. 17, 2012

(30) Foreign Application Priority Data
Dec. 28, 2011 (KR) 10-2011-0144813

(51) Int. Cl. H05K 3/40; H05K 1/02

(52) U.S. Cl. CPC H05K 3/4007; H05K 1/0296
USPC 174/257; 228/101; 228/160; 228/110.1; 228/115; 228/107; 228/112.1; 228/113; 228/198; 219/617; 174/250

(57) ABSTRACT

The present invention relates to a method for manufacturing a printed circuit board, which includes: preparing a base substrate with an electrode pad; providing a conductive material having a predetermined height; disposing the conductive material on the electrode pad; and forming a conductive post on the electrode pad by bonding the electrode pad and the conductive material, and can achieve a fine pitch and easily implement a conductive post with a high aspect ratio.

### CROSS-REFERENCE TO RELATED APPLICATIONS

Claim and incorporate by reference domestic priority application and foreign priority application as follows:

### Cross Reference to Related Application

This application claims the benefit under 35 U.S.C. Section 119 of Korean Patent Application Serial No. 10-2011-0144813, entitled filed Dec. 28, 2011, which is hereby incorporated by reference in its entirety into this application.

### BACKGROUND OF THE INVENTION

1. Field of the Invention

The present invention relates to a printed circuit board and a method for manufacturing the same, and more particularly, to a printed circuit board and a method for manufacturing the same that can achieve a fine pitch and implement a conductive post with a high aspect ratio.

2. Description of the Related Art

In recent times, high performance, high function, and miniaturization of electronic components have been demanded according to development of electronics industry. Accordingly, even in substrates for surface-mounting components, there are rising demands for high integration, thinning, and fine circuit patterns in response to miniaturization and technology integration.

Particularly, in surface-mounting technologies of electronic components on a substrate, a wire bonding method and a flip-chip bonding method are used for electrical connection between a semiconductor chip and a printed circuit board. However, since the wiring bonding method uses a wire for connection with the printed circuit board, it causes an increase in module size, requires additional processes, and has limitations in implementing a fine pitch of a circuit pattern. Thus, the flip-chip bonding method has been widely used.

Here, the flip-chip bonding method is a method of forming an external connection terminal (that is, bump) on a semiconductor chip using gold, solder, or other metals and flipping the semiconductor chip with the bump to make a surface of the semiconductor chip face a substrate, contrary to a conventional mounting method using wire bonding.

The flip-chip bonding method has gained a significant achievement by application of a flip-chip technology that replaces the wiring bonding, but refinement of a bump pitch is a still difficult problem.

Accordingly, in order to form a finer bump pitch than a solder bump forming method, a technology of forming a metal post using an electrolytic copper plating process instead of solder paste or solder balls has been developed.

FIG. 1 is a cross-sectional view showing a metal post where an undercut is formed, and FIG. 2 is a cross-sectional view showing a metal post where a dimple is formed, FIG. 3 is a cross-sectional view showing the state in which a seed layer formed under a metal post is partially removed, and FIG. 4 is a cross-sectional view showing a metal post whose position is deviated. According to the prior art, after a base substrate 11 with an electrode pad 11a is prepared, a seed layer 12 is formed on the base substrate 11, a dry film 13 having an opening for exposing the electrode pad 11a is applied on the seed layer 12, and the opening is plated to form a metal post 14. After that, the metal post 14 is completed by peeling the dry film 13 and etching the seed layer 12.

As in FIG. 1, in the metal post according to the prior art, if the opening is not completely formed in the dry film, an undercut may occur as in region A, thus deteriorating reliability of the metal post.

Further, since a thickness of the plating formed in the opening is thick compared to the electrode pad, it takes a long plating time. As in region B of FIG. 2, since a dimple occurs, a planarization process for removing the dimple is added.

In addition, as in region C of FIG. 3, when etching the seed layer, the seed layer formed under the metal post may be removed together, and a surface of the metal post may be etched to form roughness. Like this, the roughness formed on the surface of the metal post causes easy oxidation.

And, as in FIG. 4, when forming the opening in the dry film, if position matching of the opening is not accurate, the metal post whose position is deviated is formed and thus has a structure vulnerable to stress.

### SUMMARY OF THE INVENTION

The present invention has been invented in order to overcome the above-described problems and it is, therefore, an object of the present invention to provide a printed circuit board and a method for manufacturing the same that can achieve a fine pitch and easily implement a conductive post with a high aspect ratio by bonding a conductive material to an electrode pad after disposing the conductive material cut to a desired height on the electrode pad.

In accordance with one aspect of the present invention to achieve the object, there is provided a method for manufacturing a printed circuit board including the steps of: preparing a base substrate with an electrode pad; providing a conductive material having a predetermined height; disposing the conductive material on the electrode pad; and forming a conductive post on the electrode pad by bonding the electrode pad and the conductive material.

The step of providing the conductive material having a predetermined height may provide the conductive material having a height to be formed by cutting the conductive material formed in a wire shape to the height to be formed.

The step of disposing the conductive material on the electrode pad may dispose the conductive material on the electrode pad by moving the conductive material to the electrode pad through a jig.

The step of disposing the conductive material on the electrode pad may include the steps of forming a hole passing through the jig; inserting the conductive material in the hole; and disposing the conductive material on the electrode pad by moving the jig in which the conductive material is inserted to the base substrate.

The step of inserting the conductive material in the hole may insert the conductive material in the hole using any one method selected from a vibration absorption method and a vacuum absorption method.

The step of forming the hole passing through the jig may form the hole passing through the jig using any one means selected from a mechanical means and a chemical means.

The jig may be made of a polymer compound or a metal material.

The step of forming the conductive post on the electrode pad by bonding the electrode pad and the conductive material may bond the electrode pad and the conductive material by applying energy to the conductive material to diffuse the conductive material on the electrode pad.

The step of forming the conductive post on the electrode pad by bonding the electrode pad and the conductive material may bond the electrode pad and the conductive material using any one method selected from diffusion welding, spot welding, butt welding, ultrasonic welding, cold pressure welding, explosive welding, friction welding, inertia welding, induction welding, thermit welding, flash welding, percussion welding, seam welding, and projection welding.

The method for manufacturing a printed circuit board may further include the step of forming a resist having an opening for exposing the electrode pad on the base substrate after the step of preparing the base substrate with the electrode pad.

The conductive post may be formed with an aspect ratio of greater than 1.

The conductive post may be made of copper.

In accordance with another aspect of the present invention to achieve the object, there is provided a printed circuit board including: a base substrate with an electrode pad; a resist formed on the base substrate to have an opening for exposing the electrode pad; and a conductive post formed on the electrode pad to have a predetermined height, wherein the conductive post may have a flat surface.

The conductive post may be formed vertical to the electrode pad, and the conductive post may be formed by cutting a conductive material formed in a wire shape to a height to be formed.

The conductive post may be formed in a cylindrical shape.

The conductive post may be formed with an aspect ratio of greater than 1.

The conductive post may be made of copper.

The conductive post may be formed by bonding the conductive material to the electrode pad after disposing the conductive material cut to the height to be formed on the electrode pad through a jig.

The disposition of the conductive material cut to the height to be formed on the electrode pad through the jig may dispose the conductive material on the electrode pad by forming a hole passing through the jig, inserting the conductive material in the hole, and moving the jig in which the conductive material is inserted to the base substrate.

The bonding of the conductive material to the electrode pad may bond the electrode pad and the conductive material by applying energy to the conductive material to diffuse the conductive material on the electrode pad.

The bonding of the electrode pad and the conductive material may bond the electrode pad and the conductive material using any one method selected from diffusion welding, spot welding, butt welding, ultrasonic welding, cold pressure welding, explosive welding, friction welding, inertia welding, induction welding, thermit welding, flash welding, percussion welding, seam welding, and projection welding.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view showing a metal post where an undercut is formed;

FIG. 2 is a cross-sectional view showing a metal post where a dimple is formed;

FIG. 3 is a cross-sectional view showing the state in which a seed layer formed under a metal post is partially removed;

FIG. 4 is a cross-sectional view showing a metal post whose position is deviated;

FIG. 5 is a cross-sectional view of a printed circuit board in accordance with an embodiment of the present invention;

FIGS. 6 to 10 are cross-sectional views showing a process of manufacturing a printed circuit board in accordance with an embodiment of the present invention; and

FIGS. 11a and 11b are enlarged views of surfaces of conductive posts manufactured in accordance with the prior art and an embodiment of the present invention.

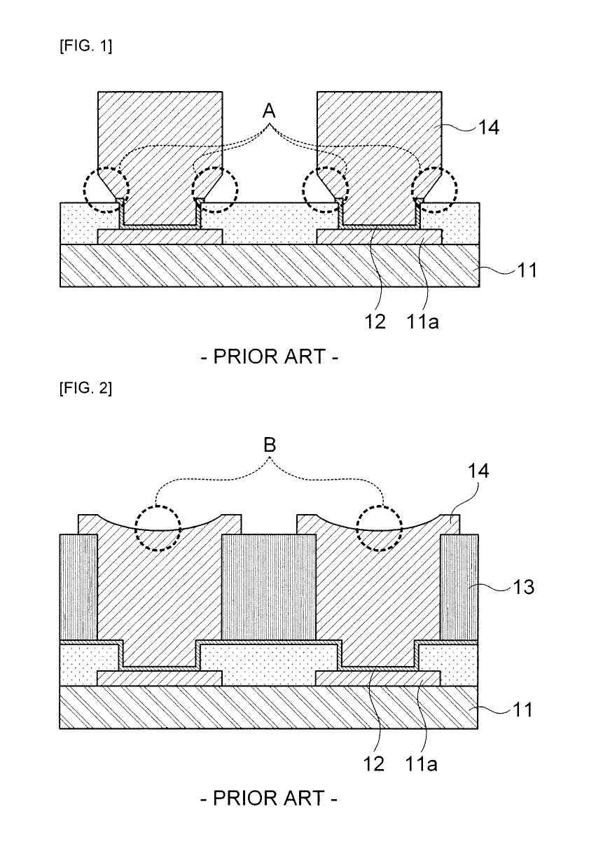

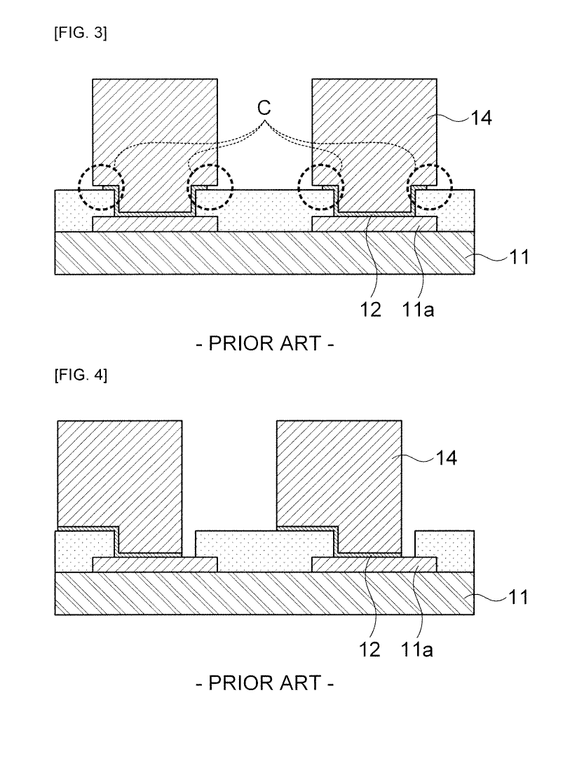

### DETAILED DESCRIPTION OF THE PREFERABLE EMBODIMENTS

The terms or words used in the present specification and claims should not be interpreted as being limited to typical or dictionary meanings, but should be interpreted as having meanings and concepts relevant to the technical spirit of the present invention based on the rule according to which an inventor can appropriately define the concept of the term to describe his/her own invention in the best manner.

Therefore, configurations shown in embodiments and the drawings of the present invention rather are examples of the most exemplary embodiment and do not represent all of the technical spirit of the invention. Thus, it will be understood that various equivalents and modifications that replace the configurations are possible when filing the present application.

Hereinafter, embodiments of the present invention will be described in detail with reference to the accompanying drawings.

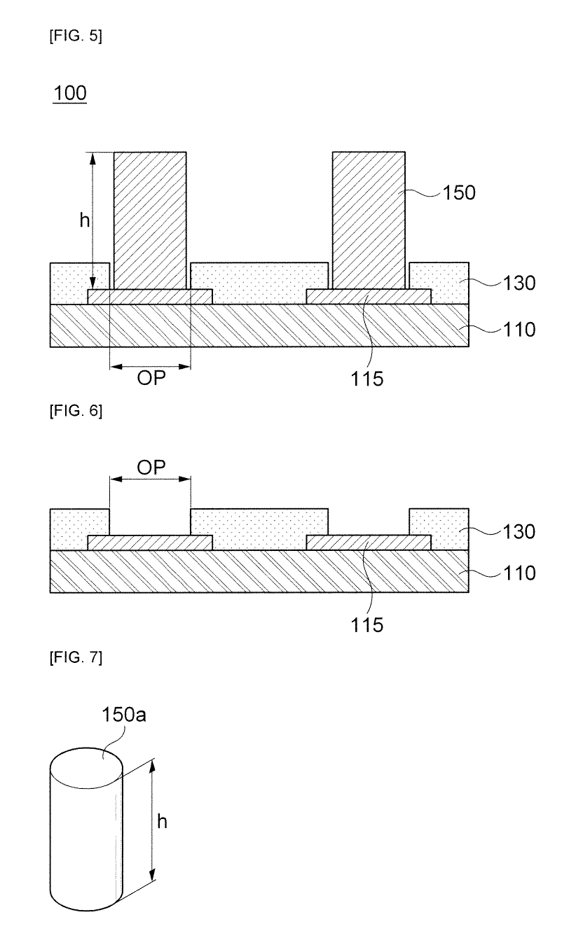

FIG. 5 is a cross-sectional view of a printed circuit board in accordance with an embodiment of the present invention.

As shown in FIG. 5, a printed circuit board 100 includes a base substrate 110, a resist 130, and a conductive post 150.

First, the base substrate 110, which is a means of supporting the printed circuit board 100, may be made of various materials, which have low electrical conductivity and hardly pass current, such as prepreg, polyimide, polyethyeleneterepthalate (PTE), cyanide ester, Ajinomoto build-up film (ABF), and epoxy.

Here, configuration of the printed circuit board as in FIG. 5 is only an example, the printed circuit board may be a single-sided printed circuit board, a both-sided printed circuit board, or a multilayer printed circuit board, and technical features of the present invention can be equally applied thereto.

The base substrate 110 may have an electrode pad 115 formed on an upper surface thereof, and the electrode pad 115 may be formed by various methods such as a subtractive method, an additive method, and a semi-additive method.

At this time, the electrode pad 115 may be made of a metal material such as copper (Cu), silver (Ag), gold (Au), aluminum (Al), iron (Fe), titanium (Ti), tin (Sn), nickel (Ni), or molybdenum (Mo).

The resist 130 may have an opening OP to expose the electrode pad 115 on the base substrate 110. At this time, the resist 130 may be made of various photosensitive materials such as photo resist, photo solder resist, and dry film and can be replaced with various materials without being limited to the above materials.

The conductive post 150, which is a means formed with a predetermined height (h) on the electrode pad 115, may have a flat surface.

More specifically, after a conductive material 150a having a cylindrical wire shape is prepared, the conductive material 150a is cut to a height (h) to be formed. After that, the conductive post 150 is formed through a process of disposing the cut conductive material 150a on the electrode pad 115 and bonding the conductive material 150a and the electrode pad 115.

Like this, since the conductive post 150 can be formed by bonding the conductive material 150a having a flat surface to the electrode pad 115, it is possible to prevent roughness from being formed on the surface of the conductive post due to etching for removing a seed layer. Further, it is possible to prevent oxidation from easily occurring on the surface of the conductive post whose surface area is increased due to roughness and easily implement a smooth flow of underfill.

And, the conductive post 150 may be formed vertical to the electrode pad 115. That is, in the prior art, the conductive post may be formed in an incomplete shape due to position matching when opening a dry film, but in an embodiment of the present invention, it is possible to be structurally resistant to external stress since the conductive post 150 can be formed always vertical to the electrode pad 115.

Further, the conductive post 150 may be formed with an aspect ratio of greater than 1. More particularly, an aspect ratio means a height (h) of the conductive post 150/a diameter of the conductive post 150. It was difficult to form a conductive post having a desired height by a plating method in accordance with the prior art, but since an embodiment of the present invention uses a method of cutting the conductive material 150a to a desired height and processing the conductive material 150a, it is possible to manufacture the conductive post 150 as long as a desired length or height.

Moreover, the conductive post 150 may be made of copper (Cu), and in addition, may be made of various materials such as silver (Ag), gold (Au), aluminum (Al), iron (Fe), titanium (Ti), tin (Sn), nickel (Ni), and molybdenum (Mo).

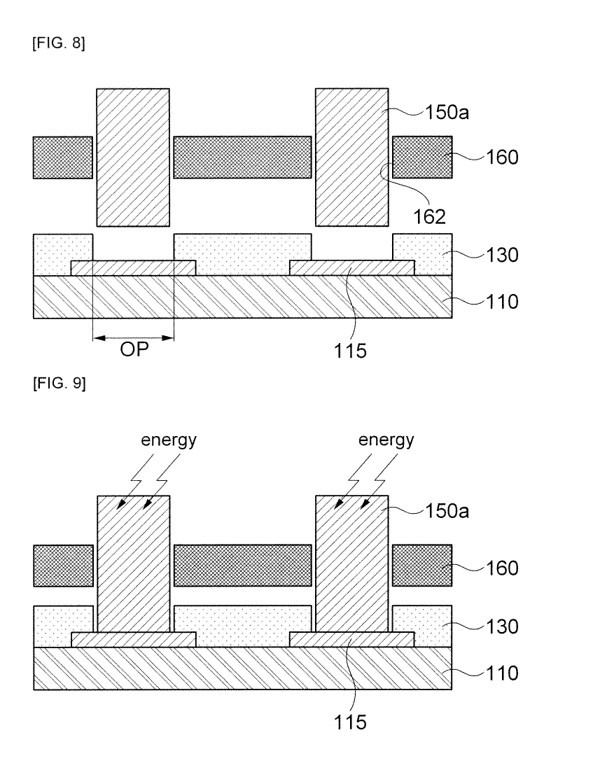

More particularly describing the process of forming the conductive post described above, the conductive post 150 can be formed through the process of disposing the conductive material 150a on the electrode pad 115 through a jig 160 shown in FIG. 8 and bonding the conductive material 150a and the electrode pad 115. First, a hole 162 is formed through the jig 160, the conductive material 150a is inserted in the hole 162, and the jig 160 in which the conductive material 150a is inserted is moved to the base substrate 110 to dispose the conductive material 150a on the electrode pad 115.

After that, the electrode pad 115 and the conductive material 150a are bonded by applying energy to the conductive material 150a to diffuse the conductive material 150a on the electrode pad 115.

At this time, the electrode pad and the conductive material can be bonded by any one method selected from diffusion welding, spot welding, butt welding, ultrasonic welding, cold pressure welding, explosive welding, friction welding, inertia welding, induction welding, thermit welding, flash welding, percussion welding, seam welding, and projection welding.

Like this, the process of forming the conductive post will be described in detail in the following process of manufacturing a printed circuit board.

Hereinafter, a process of manufacturing a printed circuit board in accordance with an embodiment of the present invention will be described.

FIGS. 6 to 10 are cross-sectional views showing a process of manufacturing a printed circuit board in accordance with an embodiment of the present invention.

As shown in FIG. 6, a base substrate 110 with an electrode pad 115 is prepared. At this time, a resist 130 having an opening (OP) for exposing the electrode pad 115 may be further formed on the base substrate 110.

Here, the base substrate 110, which is a means of supporting a printed circuit board 100, may be made of various materials, which have low electrical conductivity and hardly pass current, such as prepreg, polyimide, polyethyeleneterepthalate (PET), cyanide ester. Ajinomoto build-up film (ABF), and epoxy.

Further, the electrode pad 115 may be formed on an upper surface of the base substrate 110, and the electrode pad 115 may be formed by various methods such as a subtractive method, an additive method, and a semi-additive method.

At this time, the electrode pad 115 may be made of a metal material such as copper (Cu), silver (Ag), gold (Au), aluminum (Al), iron (Fe), titanium (Ti), tin (Sn), nickel (Ni), or molybdenum (Mo).

The resist 130, which is a means have an opening OP for exposing the electrode pad 115 on the base substrate 110, may be made of various photosensitive materials such as photo resist, photo solder resist, and dry film and can be replaced with various materials without being limited to the above materials.

Next, as in FIG. 7, a conductive material 150a having a predetermined height (h) is provided. At this time, after the conductive material 150a having a cylindrical wire shape is prepared, the conductive material 150a having a desired height is formed by cutting the conductive material 150a to a height (h) to be formed. For example, when forming a conductive material with a diameter of 100 μm and a height of 200 μm, the conductive material 150a having a desired height can be formed by cutting the conductive material with a diameter of 100 μm to a length of 200 μm.

Next, as in FIG. 8, the conductive material 150a is disposed on the electrode pad 115 by moving the conductive material 150a to the electrode pad 115 through a jig 160.

More particularly describing the process of disposing the conductive material on the electrode pad as above, a hole 162 is formed through the jig 160, the conductive material 150a cut to a predetermined height is inserted in the hole 162, and the jig 160 in which the conductive material 150a is inserted is moved to the base substrate 110 to dispose the conductive material 150a on the electrode pad 115.

At this time, the jig 160 may consist of a sheet type polymer compound or metal material, and the hole 160 passing through the jig 160 may be formed by any one means selected from a mechanical means and a chemical means. That is, the hole 162 with a desired diameter may be formed in the jig 160 using various drills such as a computer numerical control (CNC) drill and an X-ray drill in addition to various lasers such as ultraviolet (UV) laser and carbon dioxide (CO2) laser that can form a hole. Further, the hole 162 with a desired diameter may be formed by etching the jig 160 using a chemical material.

Next, the conductive material 150a may be inserted in the hole 160 using any one method selected from a vibration absorption method and a vacuum absorption method. At this time, the vacuum absorption method means a method of absorbing articles with vacuum and transferring the articles in a factory automation line.

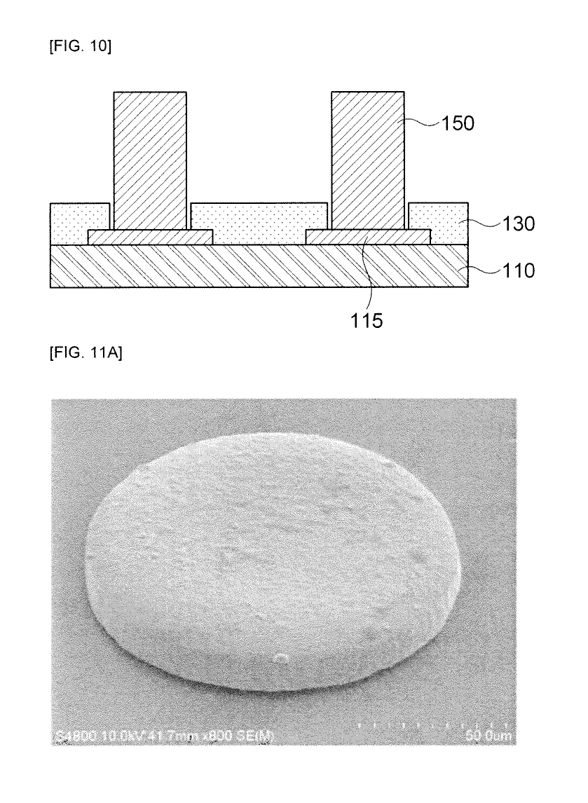

Next, as in FIG. 9, the electrode pad 115 and the conductive material 150a are bonded by applying energy to the conductive material 150a to diffuse the conductive material 150a on the electrode pad 115.

That is, since the state in which the conductive material 150a is disposed on the electrode pad 115 using the jig 160 is a physically/chemically unfixed state, when applying energy in this state, the electrode pad 115 and the conductive material 150a can be physically/chemically bonded to be fixed by a principle of metal diffusion. At this time, the electrode pad 115 and the conductive material 150a can be bonded using any one method selected from diffusion welding, spot welding, butt welding, ultrasonic welding, cold pressure welding, explosive welding, friction welding, inertia welding, induction welding, thermit welding, flash welding, percussion welding, seam welding, and projection welding.

As in FIG. 10, a conductive post 150 is formed by removing the jig 160 and completing the bonding between the electrode pad 115 and the conductive material 150a.

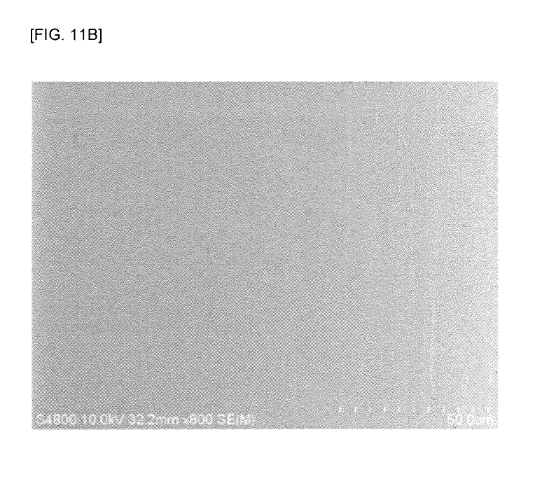

FIGS. 11a and 11b are enlarged views of surfaces of conductive posts manufactured according to the prior art and an embodiment of the present invention. As in FIG. 11a, the surface of the conductive post manufactured by a plating method according to the prior art has roughness. However, as in FIG. 11b, since the conductive post in accordance with an embodiment of the present invention uses the pre-manufactured conductive material, the surface of the conductive post is formed smoothly.

Further, it was difficult to form the conductive post having a desired height by a plating method in accordance with the prior art, but since an embodiment of the present invention can easily manufacture the conductive post by cutting the cylindrical conductive material, it is possible to manufacture the conductive post as long as a desired length or height. Due to this, it is possible to achieve a fine pitch and implement a conductive post with a high aspect ratio.

As described above, according to the printed circuit board and the method for manufacturing the same in accordance with an embodiment of the present invention, it is possible to achieve a fine pitch and easily implement a conductive post having a high height, that is, a high aspect ratio by disposing a conductive material cut to a desired height on an electrode pad and applying energy to bond the conductive material to the electrode pad.

More specifically, it is possible to prevent deterioration of reliability of the conductive post due to undercuts or position matching of an opening formed in a dry film by not using the dry film. Further, it is possible to prevent an increase in plating time or addition of a planarization process due to dimples by not using a plating method. In addition, it is possible to prevent a seed layer under the conductive post from being removed during etching or prevent roughness from being formed on a surface of the conductive post by not forming the seed layer.

Further, it is possible to form the conductive post smoothly and vertically to the electrode pad by using the pre-manufactured wire type conductive material.

In addition, it was difficult to implement a conductive post having a desired length, that is, a long length by a plating process of the prior art, but since the present invention uses a method of cutting the wire type conductive material, it is possible to easily manufacture the conductive post 150 having a desired length.

The foregoing description illustrates the present invention. Additionally, the foregoing description shows and explains only the preferred embodiments of the present invention, but it is to be understood that the present invention is capable of use in various other combinations, modifications, and environments and is capable of changes and modifications within the scope of the inventive concept as expressed herein, commensurate with the above teachings and/or the skill or knowledge of the related art. The embodiments described hereinabove are further intended to explain best modes known of practicing the invention and to enable others skilled in the art to utilize the invention in such, or other, embodiments and with the various modifications required by the particular applications or uses of the invention. Accordingly, the description is not intended to limit the invention to the form disclosed herein. Also, it is intended that the appended claims be construed to include alternative embodiments.

What is claimed is:

1. A method for manufacturing a printed circuit board, comprising:
preparing a base substrate with an electrode pad;
providing a conductive material having a predetermined height;
disposing the conductive material on the electrode pad; and
forming a conductive post on the electrode pad by bonding the electrode pad and the conductive material.

2. The method for manufacturing a printed circuit board according to claim 1, wherein providing the conductive material having a predetermined height provides the conductive material having a predetermined height by cutting the conductive material formed in a wire shape to a height to be formed.

3. The method for manufacturing a printed circuit board according to claim 1, wherein disposing the conductive material on the electrode pad disposes the conductive material on the electrode pad by moving the conductive material to the electrode pad through a jig.

4. The method for manufacturing a printed circuit board according to claim 3, wherein disposing the conductive material on the electrode pad comprises:
forming a hole passing through the jig;
inserting the conductive material in the hole; and
disposing the conductive material on the electrode pad by moving the jig in which the conductive material is inserted to the base substrate.

5. The method for manufacturing a printed circuit board according to claim 4, wherein inserting the conductive material in the hole inserts the conductive material in the hole using any one method selected from a vibration absorption method and a vacuum absorption method.

6. The method for manufacturing a printed circuit board according to claim 4, wherein forming the hole passing through the jig forms the hole passing through the jig using any one means selected from a mechanical means and a chemical means.

7. The method for manufacturing a printed circuit board according to claim 3, wherein the jig is made of a polymer compound or a metal material.

8. The method for manufacturing a printed circuit board according to claim 1, wherein forming the conductive post on the electrode pad by bonding the electrode pad and the conductive material bonds the electrode pad and the conductive material by applying energy to the conductive material to diffuse the conductive material on the electrode pad.

9. The method for manufacturing a printed circuit board according to claim 8, wherein forming the conductive post on the electrode pad by bonding the electrode pad and the conductive material bonds the electrode pad and the conductive material using any one method selected from diffusion welding, spot welding, butt welding, ultrasonic welding, cold pressure welding, explosive welding, friction welding, inertia welding, induction welding, thermit welding, flash welding, percussion welding, seam welding, and projection welding.

10. The method for manufacturing a printed circuit board according to claim 1, further comprising, after preparing the base substrate with the electrode pad, forming a resist having an opening for exposing the electrode pad on the base substrate.

11. The method for manufacturing a printed circuit board according to claim 1, wherein the conductive post is formed with an aspect ratio of greater than 1.

12. The method for manufacturing a printed circuit board according to claim 1, wherein the conductive post is made of copper.

13. A printed circuit board comprising:
a base substrate with an electrode pad;
a resist formed on the base substrate to have an opening for exposing the electrode pad; and
a conductive post formed on the electrode pad to have a predetermined height, wherein the conductive post has a flat surface.

14. The printed circuit board according to claim 13, wherein the conductive post is formed vertical to the electrode pad.

15. The printed circuit board according to claim 13, wherein the conductive post is formed with an aspect ratio of greater than 1.

16. The printed circuit board according to claim 13, wherein the conductive post is made of copper.

17. The printed circuit board according to claim 13, wherein the conductive post is formed by cutting a conductive material formed in a wire shape to a height to be formed.

18. The printed circuit board according to claim 13, wherein the conductive post is formed in a cylindrical shape.

19. The printed circuit board according to claim 17, wherein the conductive post is formed by bonding the conductive material to the electrode pad after disposing the conductive material cut to the height to be formed on the electrode pad through a jig.

20. The printed circuit board according to claim 19, wherein the disposition of the conductive material cut to the height to be formed on the electrode pad through the jig disposes the conductive material on the electrode pad by forming a hole passing through the jig, inserting the conductive material in the hole, and moving the jig in which the conductive material is inserted to the base substrate.

21. The printed circuit board according to claim 19, wherein the bonding of the conductive material to the electrode pad bonds the electrode pad and the conductive material by applying energy to the conductive material to diffuse the conductive material on the electrode pad.

22. The printed circuit board according to claim 21, wherein the bonding of the electrode pad and the conductive material bonds the electrode pad and the conductive material using any one method selected from diffusion welding, spot welding, butt welding, ultrasonic welding, cold pressure welding, explosive welding, friction welding, inertia welding, induction welding, thermit welding, flash welding, percussion welding, seam welding, and projection welding.
